(19) United States
(12) Patent Application Publication
(10) Pub. No.: US 2007/0284758 A1
(43) Pub. Date: Dec. 13, 2007

(54) Electronics package and associated method

(75) Inventors: Jian Zhang, Schenectady, NY (US); Davide Louis Simone, Clifton Park, NY (US); Christopher Michael Carter, Gulfport, MS (US); Laura Jean Meyer, Rio Rancho, NM (US); Charles Adrian Becker, Niskayuna, NY (US); Florian Johannes Schattenmann, Ballston Lake, NY (US); Sandeep Shrikant Tonapi, Niskayuna, NY (US); Slawomir Rubinsztajn, Ballston Spa, NY (US); Christopher Fred Keimel, Schenectady, NY (US)

Correspondence Address: GENERAL ELECTRIC COMPANY;GLOBAL RESEARCH, PATENT DOCKET RM. BLDG. K1-4A59, NISKAYUNA, NY, 12309, US

(73) Assignee: General Electric Company, Schenectady, NY (US)

(21) Appl. No.: 11/438,657

(22) Filed: May 22, 2006

(51) Int. Cl. H01L 23/48; H01L 23/52; H01L 29/40

(52) U.S. Cl. 257/780

(57) ABSTRACT

An electronics package is provided. The electronics package may include an underfill layer having a surface that defines an opening. The electronics package may include a polymer bump structure disposed within the opening. A laminate for use as an underfill layer is provided. Associated methods are provided.

### BACKGROUND

1. Technical Field

The invention includes embodiments that may relate to an electronics package. The invention includes embodiments that may relate to a method of making and/or using the electronics package.

2. Discussion of Related Art

The trend of microelectronics products may include higher-density, increased efficiency and speed, and lower cost of components. A flip chip assembly may facilitate the trend by increasing density and reducing cost relative to previous manufacturing methods and devices. In a flip chip assembly, electrical connections may be made by compressing metal contact points, or solder balls between the chip and the substrate. A flip chip assembly may refer to electrical connection of face-down (hence, “flipped”) electronic components onto substrates, circuit boards, or carriers, by means of conductive bumps on the chip bond pads.

Sometimes, mechanical stress may cause the failure of the compressed solder balls. The stress may be attributed to thermal cycling of components having a coefficient of thermal expansion (CTE) mismatch, such as between the flip chip and the substrate. These stresses may initiate and propagate cracks in the solder balls, which may lead to loss of electrical conductivity or device failure.

The thermal expansion (CTE) mismatch of the solid metal bump relative to the adhesive that holds the metal bumps to the substrate may be problematic. It may be desirable to have an adhesive that has a coefficient of thermal expansion similar to, or the same as, the substrate.

It may be desirable to obtain a structure, system, and/or method for securing a chip to a substrate having determined properties and/or features that might not otherwise be available.

### BRIEF DESCRIPTION

In one embodiment, an electronics package is provided. The electronics package may include an underfill layer having a surface that defines an opening. The electronics package may further include a material selected from the group consisting of an inherently electrically conductive polymer and an electrically conductive filler, and mixtures thereof.

In one embodiment, a wafer level underfill assembly may include an electronics package according to an embodiment of the invention.

In one embodiment, a method of making an electronics package may include disposing a bump structure in an opening. The opening may be defined by a surface of an underfill layer to form a laminate. Alternatively, the method may include disposing a bump structure on a substrate, and contacting an underfill layer material to the bump structure to form the laminate.

In one embodiment, a laminate is provided. The laminate may include a B-staged underfill layer having a polymeric bump structure disposed therein.

### BRIEF DESCRIPTION OF THE DRAWINGS

These and other features and aspects may be apparent in view of the detailed description and accompanying drawing figures in which like reference numbers indicate parts that are the same from figure to figure.

FIG. 1 is a schematic cross-sectional view of a wafer level underfill assembly employing an electronics package in accordance with an embodiment of the invention.

FIG. 2 is a schematic cross-sectional view of a wafer level assembly in accordance with an embodiment of the invention.

FIG. 3 is a schematic cross-sectional view of a distribution of cavities in an underfill layer on a substrate in accordance with an embodiment of the invention.

FIG. 4 is a flow chart illustrating a method for making an electronics package in accordance with an exemplary embodiment.

### DETAILED DESCRIPTION

The invention includes embodiments that may relate to an electronics package. The invention includes embodiments that may relate to a method of making and/or using the electronics package. The invention may include embodiments that may relate to a wafer level underfill assembly.

As used herein, a term electronics package may refer to an assembly having a chip attached to a substrate by electrically conductive polymer bumps, where an underfill layer may surround the electrically conductive polymer bumps. As used herein, electrically conductive may include the ability to transport electric charge when an electric potential difference is impressed across separate points of the electrically conductive material. Thermally conductive may include the ability to conduct heat, and may refer to a physical constant for a quantity of heat that may pass through a determined volume in unit of time for units involving a difference in temperature across the volume.

The term “free” may be used in combination with a term, and may include insubstantial or trace amount while still being considered free of the modified term. For example, free of solvent or solvent-free, and like terms and phrases, may refer to an instance in which a significant portion, some, or all of the solvent has been removed from a solvated material, for example, during B-staging. B-staging a underfill layer material layer, and related terms and phrases, may include at least partially solidifying a material by one or more of heating for a determined amount of time, optionally under vacuum, to remove some or all of a solvent; advancing a cure or cross-linking a curable underfill layer material from an uncured state to a partially, but not completely, cured state; or cross-linking a first of a plurality of cross-linkable materials in a mixture of materials having differing cure properties. The B-staged material, after B-staging, may be one or more of tack-free and/or solid. Tack free may refer to a surface that does not possess pressure sensitive adhesive properties at about room temperature. By one measure, a tack free surface will not adhere or stick to a finger placed lightly in contact therewith at about 25 degrees Celsius, or has a tack level expressed in Dalquist units below a determined level. Solid refers to a property such that a material does flow perceptibly under moderate stress, or has a definite capacity for resisting one or more forces (e.g., compression or tension) that may otherwise tend to deform it. In one aspect, under ordinary conditions a solid may retain a definite size and shape. As used herein, under bump metallurgy (UBM) may refer to a structure, which serves as the base of the bump and may include an adhesion layer, a barrier layer and an electrically conductive and wettable layer.

Approximating language, as used herein throughout the specification and claims, may be applied to modify quantitative representation that could permissibly vary without resulting in a change in the basic function to which it is related. Accordingly, a value modified by a term or terms, such as “about”, may not to be limited to the precise value specified. In at least some instances, the approximating language may correspond to the precision of an instrument for measuring the associated value.

An electronics package according to an embodiment of the invention may include an underfill layer. An inner surface of the underfill layer may define an opening that extends from a first surface into and through the underfill layer to a second surface. An electrically conductive polymer may be disposed within the opening. The electrically conductive polymer may conform to a shape of opening to contact the underfill layer inner surface.

The underfill layer may be disposed on a surface of the substrate. A suitable substrate may be a layer of semiconductor material, plastic, a printed circuit board, or the like. In one embodiment, the substrate is a ceramic-coated metal core board. The substrate may have electrical interconnects and other under-chip metallurgy, such as a contact pad or a passivation layer. The contact pads may be conductive. Suitable contact pad material may include one or more of copper, silver, aluminum, nickel, cobalt, tin, gold, platinum, iron, or a combination of two or more thereof. Suitable passivation layers may include a polyimide, an oxide, silicon oxy nitride, silicon nitride, or benzocyclobutene (BCB).

Suitable underfill layers may conduct thermal energy, may resist moisture or other environmental hazards, may provide mechanical strength to the electronics package, and may compensate for thermal expansion differential of the chip relative to the substrate. To compensate, the underfill layer may mechanically lock the chip and substrate together so that differences in thermal expansion have a reduced risk of breaking or damaging an electrical connection between the chip and a substrate.

The underfill layer may be electrically insulative. Electrical insulation may reduce or eliminate short-circuiting between the electronic components of the chip or of the substrate.

The underfill layer may include a material that is polymerizable or thermosettable. In one embodiment, the polymerization may be at least partially accomplished by radiation, such as ultraviolet radiation. In one embodiment, the polymerization of the underfill layer may be at least partially achieved by heating the underfill layer material. In one embodiment, the underfill layer material may be heat cured to form permanent bond. In one embodiment, the underfill layer may include a thermoplastic.

Suitable underfill layer materials may include one or more of polycarbonate, polyimide, polystyrene, polyester, polysulfone, polyether imide, poly(arylene) ether, poly bismaleimide, polyamide, polyvinyl, polyamine, poly ethyl ether ketone (PEEK), or polyolefin, or a derivative or block copolymers thereof. In one embodiment, the underfill layer material may include a liquid crystalline polymer.

Suitable polyolefins may include polyethylene or polypropylene, or derivatives or analogs thereof. In one embodiment, the polyolefin may include low-density polyethylene (LDPE) or copolymers thereof.

Other suitable underfill layer materials may include one or more curable (e.g., cross-linkable) underfill layer material. Suitable curable underfill layer materials may include aromatic, aliphatic and cycloaliphatic resin-based underfill layer materials. In one embodiment, the underfill layer material may include urethane, acrylate (to include methacrylate), or oxirane (such as an epoxy), or derivatives and analogs thereof. In one embodiment, the underfill layer material may include one or more of polysiloxane resin, fluorocarbon resin, benzocyclobutene resin, polyallyl ether, polyimidoamide resin, phenol cresol resin, aromatic polyester resin, polyphenylene ether (PPE) resin, polyphenylene oxide (PPO) resin, cyanate ester, bismaleimide triazine resin, ethylene-vinylacetate or the like. Suitable cross-link mechanisms may include one or more of free radical polymerization, atom transfer, radical polymerization, ring-opening polymerization, ring-opening metathesis polymerization, anionic polymerization, or cationic polymerization.

In one embodiment, the underfill layer material may include one or more oxirane moieties, such as an epoxy. The oxirane underfill layer material may include an organic system or inorganic system with epoxy functionality, or may have a higher ring number, such as an oxetane. In one embodiment, the epoxy underfill layer material may include an aromatic epoxy underfill layer material, a cycloaliphatic epoxy underfill layer material, aliphatic epoxy underfill layer material, or a mixture of two or more thereof.

Useful epoxy underfill layer materials may include those that may be produced by reaction of a hydroxyl, carboxyl or amine-containing compound with epichlorohydrin in the presence of a basic catalyst, such as a metal hydroxide. Also included may be epoxy underfill layer materials produced by reaction of a compound containing at least one and two or more carbon-carbon double bonds with a peroxide, such as a peroxyacid.

Suitable aromatic epoxy underfill layer materials may include one or more novolak epoxy underfill layer materials. In one embodiment, the epoxy underfill layer material may include one or more of bisphenol-A epoxy, bisphenol-F epoxy, resorcinol diglycidyl ether, biphenyl epoxy, or 4,4-biphenyl epoxy. In one embodiment, a polyfunctional epoxy may include one or both of divinyl benzene dioxide or 2-glycidyl phenyl glycidyl ether. Suitable trifunctional aromatic epoxy underfill layer materials may include, for example, triglycidyl isocyanurate epoxy.

In one embodiment, the underfill layer may include an adhesive additive. The adhesive additive may facilitate one or more of adhesion between the underfill layer and the electrically conductive polymer, cohesion of the electrically conductive polymer, water resistance, and the like. The adhesive additive may be selected based on compatibility (or in some cases its incompatibility) with the underfill layer material. Where distinct layer boundary definitions may be desirable, incompatible or non-miscible materials may be used as the adhesive additive and the underfill layer material.

The underfill layer material may be in an amount greater than about 5 volume percent of the total volume of the underfill layer. In one embodiment, the underfill layer material may be in a range of from about 5 volume percent to about 10 volume percent, from about 10 volume percent to about 15 volume percent, from about 15 volume percent to about 20 volume percent, or greater than about 20 volume percent. In one embodiment, the underfill layer material may be in an amount of less than about 20 volume percent of the total volume of the underfill layer.

The underfill layer material may be a B-stageable material that may respond to, for example, a B-staging treatment to form one or more of a non-flowable, solid, or tack free layer, a partially polymerized layer, or a solvent free layer. In one embodiment, the material of the underfill layer is B-stageable, and in other embodiments, the underfill layer has been B-staged. In one embodiment, the underfill layer is an ultraviolet radiation sensitive B-stageable material. The B-staging may be accomplished, for example, by solvent reduction, partial polymerization, or the like.

The B-stageable material, prior to B-staging, may include one or more solvent. Suitable solvents may include one or more organic solvents, such as 1-methoxy-2-propanol, methoxy propanol acetate, butyl acetate, methoxy-ethyl ether, methanol, ethanol, isopropanol, ethylene glycol, methyl-ethyl ketone, cyclo-hexanone, benzene, toluene, xylene, and cellosolves such as ethylcellosolve, ethyl acetate, cellosolve acetate, butyl cellosolve acetate, carbitol acetate, and butyl carbitol acetate, and combinations of two or more thereof. In at least one embodiment, the solvent may be extracted to form a B-staged layer. Optionally, some residual solvent may remain in the underfill layer after B-staging to form the B-staged layer.

If the underfill layer initially contains solvent, B-staging the B-stageable layer may be for a sufficient time at a sufficient temperature and a sufficient vacuum to achieve the underfill layer having a B-staged material adhered to the substrate, where the underfill layer may be free of solvent. B-staging of the B-stageable layer may be performed at a temperature greater than room temperature. In one embodiment, the B-staging temperature may be in a range of from about 50 degrees Celsius to about 65 degrees Celsius, from about 65 degrees Celsius to about 80 degrees Celsius, from about 80 degrees Celsius to about 220 degrees Celsius, from about 220 degrees Celsius to about 235 degrees Celsius, from about 235 degrees Celsius to about 250 degrees Celsius, or greater than about 250 degrees Celsius.

B-staging of the B-stageable layer may be performed at a controlled pressure. In one embodiment, the pressure may be about ambient pressure. In one embodiment, the pressure may be a negative pressure of less than about 10 mm Hg (millimeters of Mercury), or about 10 Torr. In one embodiment the pressure may be in a range of from about 10 mm Hg (about 10 Torr) to about 50 mm Hg (about 50 Torr), from about 50 mm Hg (about 50 Torr) to about 75 mm Hg (about 75 Torr), from about 75 mm Hg (about 75 Torr) to about 200 mm Hg (about 200 Torr), from about 200 mm Hg (about 200 Torr) to about 225 mm Hg (about 225 Torr), from about 225 mm Hg (about 225 Torr) to about 250 mm Hg (about 250 Torr), or greater than about 250 mm Hg (about 250 Torr). In one embodiment, B-staging may be affected at about 95 degrees Celsius at less than about 10 mm Hg (less than about 10 Torr), for about 90 minutes.

B-staging the B-stageable layer may be performed in a period greater than about 30 seconds. In one embodiment, the B-staging time may be in a range of from about 1 minute to about 10 minutes, from about 10 minutes to about 30 minutes, from about 30 minutes to about 60 minutes, from about 60 minutes to about 70 minutes, from about 70 minutes to about 240 minutes, from about 240 minutes to about 270 minutes, from about 270 minutes to about 300 minutes, or greater than about 300 minutes.

If a B-staging method other than solvent removal is selected, the pre-formed structure of the electronics package having the B-stageable underfill layer and/or the electrically conductive polymer may be transformed from a liquid to a B-staged layer, for example, by partially cross-linking a reactive monomer, and/or partially solidifying the B-stageable underfill layer. The B-stageable underfill layer may include two or more materials, where each material has a different curing mechanism relative to each other. For example, the underfill layer may include a first and a second material, where the first material may be cured by cross-linking and the second material may be cured by partial solidification.

As noted herein, B-staged underfill layer may be one or more of solid, tack-free, or hard. In one embodiment, the underfill layer material may include one or more additives, hardeners, catalysts, or combinations of two or more thereof.

The underfill layer material may include additives which may affect one or more attributes of the underfill layer, such as minimum width, viscosity, cure profile, adhesion, electrical properties, thermal properties (e.g., thermal conductivity), chemical resistance (e.g., moisture resistance, solvent resistance), glass transition, thermal conductivity, heat distortion temperature, and the like.

A curing agent or hardener suitable to cure or harden the determined material may be included in the underfill layer. Suitable curing agents may include one or more free radical initiators, such as azo compounds, peroxides, and the like. Suitable azo compounds for the curing agent may include azo-bis-isobutyronitrile. Suitable hardeners, such as unsaturated carboxylic acids or anhydrides, may include one or more of maleic acid, fumaric acid, citaconic acid, chloromaleic acid allyl succinic acid, itaconic acid, mesaconic acid, and anhydrides thereof.

Suitable peroxides may include one or more organic peroxide, such as those having the formula R—O—O—H or R—O—O—R′. In one embodiment, the organic peroxide may include one or more of di-acyl, peroxy-di-carbonate, mono-peroxy-carbonate, peroxy-ketal, peroxy-ester, or di-alkyl peroxide. In one embodiment, the organic peroxide may include one or more of di-cumyl peroxide, cumyl hydro-peroxide, t-butyl peroxy-benzoate, or ketone-peroxide. In one embodiment, the peroxide may include hydro-peroxide.

The curing agent, if used, may be in an amount greater than about 0.5 weight percent. In one embodiment, the curing agent may be in a range of from about 0.1 weight percent to about 0.5 weight percent, from about 0.5 weight percent to about 1 weight percent, from about 1 weight percent to about 3 weight percent, from about 3 weight percent to about 5 weight percent, from about 5 weight percent to about 10 weight percent, from about 10 weight percent to about 15 weight percent, from about 15 weight percent to about 25 weight percent, from about 25 weight percent to about 50 weight percent, or greater than about 50 weight percent, based on the weight of the total underfill layer material content.

A cure catalyst may be included in the electrically conductive polymer, the underfill layer material, or the underfill layer. Suitable cure catalysts may include one or more amine, imidazole, imidazolium salt, phosphine, metal salt, or salt of nitrogen-containing compound. A metal salt may include, for example, aluminum acetyl acetonate (Al(acac)₃). The nitrogen-containing molecule may include, for instance, amine compounds, di-aza compounds, tri-aza compounds, poly-amine compounds and combinations of two or more thereof. The acidic compounds may include phenol, organo-substituted phenols, carboxylic acids, sulfonic acids and combinations of two or more thereof.

The cure catalyst, if used, may be in an amount greater than about 0.5 weight percent. In one embodiment, the cure catalyst may be in a range of from about 0.1 weight percent to about 0.5 weight percent, from about 0.5 weight percent to about 1 weight percent, from about 1 weight percent to about 3 weight percent, from about 3 weight percent to about 5 weight percent, from about 5 weight percent to about 10 weight percent, from about 10 weight percent to about 15 weight percent, from about 15 weight percent to about 25 weight percent, from about 25 weight percent to about 50 weight percent, or greater than about 50 weight percent, based on the weight of the total underfill layer material content.

Further, the underfill layer may include one or more thermally conductive fillers. Also, these thermally conductive fillers may be electrically insulative to prevent short-circuiting between the electrical components of the chip and the substrate. In one embodiment, adding one or more thermally conductive fillers may increase the thermal conductivity and/or electrical resistivity of the underfill layer, or of another layer. Thermally conductive filler materials or additives may affect one or more attributes of the underfill layer, such as minimum width, viscosity, cure profile, adhesion, tack, electrical properties, chemical resistance (e.g., moisture resistance, solvent resistance), glass transition, thermal conductivity, heat distortion temperature, and the like. The thermally conductive filler may be selected for relatively high thermal conductivity, relatively low thermal conductivity, or for a different property or attribute.

In one embodiment, the thermally conductive fillers may include oxide, boride, nitride, or combinations of two or more thereof. In one embodiment, the filler may include silica. Suitable silica may include one or more of fused silica, fumed silica, or colloidal silica.

Suitable thermally conductive filler may have an average particle diameter of less than about 500 micrometers. In one embodiment, the filler may have an average particle diameter in a range of from about 1 nanometer to about 5 nanometers, from about 5 nanometers to about 10 nanometers, from about 10 nanometers to about 50 nanometers, or greater than about 50 nanometers. A suitable volume particle size distribution may be mono-modal, with a standard deviation of less than about 2. Another suitable volume particle size distribution may be bi-modal, with the relatively smaller particles sized to fill interstitial areas defined by the packed larger particles.

Thermally conductive filler may be surface treated with a compatiblizing agent, and may be further treated with a passivating agent. A suitable compatiblizing agent may include organoalkoxysilane, and a suitable passivating agent may include a silazane.

Suitable thermally conductive filler particles may have differing shapes and sizes that may be selected based on application specific criteria. Suitable shapes may include one or more of spherical particles, semi-spherical particles, rods, fibers, geometric shapes, and the like. The particles may be hollow or solid-cored, or may be porous. Long particles, such as rods and fibers may have a length that differs from a width, and may be directionally orientable relative to a plane defined by the underfill layer, orientation of such elongate particles may enhance heat transfer from the chip to the heat-dissipating unit, or heat sink.

Selection of electrically resistive filler may be based on desired end properties. The electrically resistive filler may be the same as, or different from, the thermally conductive filler. Other than the resistivity or dielectric property, the electrically resistive filler has all the characteristics of the thermally conductive filler.

The bump structure, and the opening that defines the bump structure, may have a determined shape and size. The opening defined by the underfill layer may be perpendicular to the surface of the underfill layer. The cross-section of the opening may be circular, triangular, elliptical, trapezoidal, square, rectangular, or polygonal shaped. The opening may define a volume that is cubic, cylindrical, frusto-conical, or oblate. Further, the height of the opening may be determined based on the spacing between the chip and the substrate, the thickness of the underfill layer, the electrically insulative ability of the underfill layer, the power requirements of the device, or other considerations.

The height of the opening may be less than about 100 micrometers. In one embodiment, the opening height may be in a range of from less than about 10 micrometers to about 25 micrometers, from about 25 micrometers to about 50 micrometers, from about 50 micrometers to about 75 micrometers, from about 75 micrometers to about 100 micrometers. The height of the bump structure may be the same as the opening height, or may be a determined distance more or less than the opening height. In one embodiment, the bump structure height may be in a range of from less than about 10 micrometers to about 25 micrometers, from about 25 micrometers to about 50 micrometers, from about 50 micrometers to about 75 micrometers, from about 75 micrometers to about 100 micrometers. In one embodiment, the bump structure height may be more than the opening height by more than 1 percent of the bump structure height. In one embodiment, the bump structure height may be more than the opening height by an amount that is in a range of from about 1 percent to about 2.5 percent, from about 2.5 percent to about 5 percent, from about 5 percent to about 7.5 percent, from about 7.5 percent to about 10 percent, or greater than about 10 percent of the bump structure height. The surface of the bump structure that extends outward from the underfill layer first surface may be curved. In one embodiment, the extending bump structure surface may be convex. The maximum height may be at the center of the curve. The center of the curve may coincide with the center of the opening. The bump structure surface may be rough to increase surface area, and thus increase contact surface.

In one embodiment, a pitch of the opening, or the pitch of the bump structure, which is formed by filling the opening with the electrically conductive polymer is in a range of from about 25 micrometers to about 50 micrometers, from about 50 micrometers to about 100 micrometers, or less than about 100 micrometers. Pitch refers to a distance from the center of one bump to the center of an adjacent bump. In one embodiment, the pitch may be twice the diameter of an opening. For example, the pitch of the opening having a diameter of about 50 micrometers may be about 100 micrometers. In one embodiment, the pitch may be in a range of from less than about 1 micrometer to about 10 micrometers, from about 10 micrometers to about 25 micrometers, from about 25 micrometer to about 40 micrometers, from about 40 micrometers to about 60 micrometers, or greater than about 60 micrometers.

The bump structure may include a polymer that is inherently electrically conductive, or a non-electrically conductive polymer matrix selected from the suitable materials for the underfill layer materials. In such cases where the polymer is inherently electrically conductive, the backbones or the pendant groups of the polymers may generate or propagate the charge carriers. In one embodiment, suitable inherently electrically conductive polymers may be polyconjugate, and may include one or more high-mobility conjugated polymers. The electrically conductive polymer may be conductive due to resonance stabilization and delocalization of pi electrons along the polymer backbone. The electrically conductive polymer may include a conductive carbon nanotube network. The electrically conductive polymer may include an overlapping set of molecular orbitals to provide carrier mobility to the polymer. The electrically conductive polymer may be self-organizing.

In one embodiment, the inherently electrically conductive polymer may include one or more of polyaniline; poly(3-hexylthiopene); poly(acetylene); polypyrrole; polychloroprene; poly(N-vinylimidazole); doped block copolymers of poly(4-vinylpyridine); doped block copolymers of poly(dimethylsiloxane); poly(ethylene terephthalate); polythiophene; 2-Naphthylacetylene; or poly(dioctyl-bithiophene), and derivatives of the foregoing, such as iodine-doped trans-polyacetylene, poly(phenylacetylene), and poly(methylacetylene). In one embodiment, the electrically conductive polymer may include a semi-interpenetrating polymer networks (semi-IPNs)-salt complex polymer electrolyte, such as poly(ethylene oxide)-polyurethane/polyacrylonitrile (PEO-PU/PAN).

In one embodiment, the electrically conductive polymer may be doped. Suitable dopants may include, for example, iodine, tetra-cyanoquinodimethane (TCNQ), or a protonic acid. The conductivity of the electrically conductive polymer, which is inherently conductive, may be tailored by, for example, varying the concentration of the majority carriers. For example, the electrically conductive polymer may be doped to increase the concentration of the majority carriers.

In one embodiment, the bump structure may include one or more aromatic or heteroaromatic polymers. Examples of such polymers may include polyarylene; or polyheteroarylene. Suitable polyarylene, or polyheteroarylene, may include one or more poly(p-phenylene); polynapthylene; polyanthrylene; polyacenaphthylenediyl; polyphenanthrylene; and polyacenequinone radical polymers. In one embodiment, the aromatic or heteroaromatic polymers may include a conjugated aliphatic group. Examples of such polymers may include oligomeric vinylenes having 1,4-phenylene, 2,5-dimethoxy-1,4-phenylene, or 2,5-thiophenediyl. If the aromatic or heteroaromatic polymers have a conjugated aliphatic group attached thereto, the electrical conductivity of the polymers increases with the increase in the chain length of the attached aliphatic group.

In one embodiment, the bump structure may be free of lead. In one embodiment, the bump structure may include one or more fillers. The fillers may be electrically conductive, or thermally conductive, or both electrically conductive and thermally conductive. In another embodiment, the bump structure may be free of electrically conductive filler (and therefore use an inherently electrically conductive polymer). In one embodiment, the bump structure may include both electrically conductive filler and an inherently electrically conductive polymer. Alternatively, the bump structure, rather than include inherently electrically conductive polymer, may instead include a relatively non-conductive polymer filled with electrically conductive filler. As all three permutations—i.) electrically conductive polymer alone, ii.) electrically conductive filler alone, and iii.) electrically conductive polymer plus electrically conductive filler—achieve an electrically conductive bump structure, the permutations may be referred to as the “electrically conductive polymer”, and the term refers to any of the three permutations, unless language or context indicates otherwise.

Filler materials or additives may affect one or more attributes of the bump structure, such as minimum width (bond-line thickness), viscosity, cure profile, adhesion, tack, electrical properties, chemical resistance (e.g., moisture resistance, solvent resistance), glass transition, thermal conductivity, heat distortion temperature, and the like. The filler may be selected for relatively high electrical conductivity, or for a different property or attribute.

In the same manner as the filler suitable for use in the underfill layer material, suitable thermally conductive filler may include particles and/or a liquid metal. A difference being that the bump structure further may use filler materials that are also electrically conductive. Suitable liquid metals may include gallium metal. In one embodiment, the thermally conductive filler may include the fillers as described above with regard to underfill layer.

Suitable electrically conductive fillers may include carbon or metal. In one embodiment, the electrically conductive fillers may include fibers and/or particles. Suitable electrically conductive fillers may include one or more of nanotubes (e.g., carbon nanotubes), pyrolytic graphite, carbon black, and crystalline or amorphous graphite. Other suitable electrically conductive fillers may include one or more of silver, nickel, gold, tin, indium, aluminum, gallium, boron, phosphorus, tin, or alloys or mixtures of two or more thereof.

Suitable electrically conductive filler may have an average particle diameter of less than about 500 micrometers. In one embodiment, the electrically conductive filler may have an average particle diameter in a range of from about 1 nanometer to about 5 nanometers, from about 5 nanometers to about 10 nanometers, from about 10 nanometers to about 50 nanometers, or greater than about 50 nanometers. A suitable volume particle size distribution may be mono-modal, with a standard deviation of less than about 2. Another suitable volume particle size distribution may be bi-modal, with the relatively smaller particles sized to fill interstitial areas defined by the packed larger particles. Filler may be treated with a compatiblizing agent, and may be further treated with a passivating agent. A suitable compatiblizing agent may include organoalkoxysilane, and a suitable passivating agent may include a silazane.

Suitable electrically conductive filler particles may have differing shapes and sizes that may be selected based on application specific criteria. Suitable shapes may include one or more of spherical particles, semi-spherical particles, rods, fibers, geometric shapes, and the like. The particles may be hollow or solid-cored, or may be porous. Long particles, such as rods and fibers may have a length that differs from a width, and may be directionally orientable, orientation of such elongate particles may enhance heat transfer from the chip to the heat-dissipating unit, or heat sink.

In embodiments where the bump structure is a combination of a non-conductive matrix and electrically conductive fillers, the conductivity of the electrically conductive polymer may depend on one or more of: the electrical conductivity of the filler, the shape of the filler particulate, and surface characteristics of the fillers—such as wetability. For example, filler having a high electrical conductivity may result in a high conductivity electrically conductive polymer. In another example, for a fibrous-shaped filler, the electrical conductivity of the electrically conductive polymer may be enhanced due to more inter-particle contacts. More inter-particle contact area may provide low-resistance conductive paths to the charge carriers. Similarly, a lower wetability of the filler, or a mismatch in the surface tensions of the filler and the matrix, may result in aggregation of the fillers in the matrix, possibly resulting in poor network of the filler particles and lower conductivity of the overall bump structure. However, when surface tensions of the matrix and the filler are similar to, or same, the distribution of the filler in the matrix may be relatively homogeneous, thereby providing “chaining” or network formation in the matrix, which may result in higher conductivity.

In addition to electrically conductive fillers, the fillers in the electrically conductive polymer having a non-conductive matrix may also include any or all of the thermally conductive fillers disclosed with reference to the underfill layer. As with the fillers for the underfill layer, the electrically conductive polymer fillers may be treated with a compatiblizing agent, and may be further treated with a passivating agent. A suitable compatiblizing agent may include organoalkoxysilane, and a suitable passivating agent may include a silazane.

The electrical resistivity of the electrically conductive polymer, after cure, may be less than about 10⁻⁵ Ohm centimeter. In one embodiment, the electrical resistivity may be in a range of from about 10⁻⁵ Ohm centimeter to about 10⁻⁶ Ohm centimeter, or lower than about 10⁻⁶ Ohm. In one embodiment, the volume resistivity may be less than about 0.01 Ohm per centimeter.

The electrical dispersivity or impendence may be distinguishable in a dielectric layer relative to a conductive layer. In a dielectric layer, induced or permanent dipoles may affect the electrical character of the material. By way of contrast, the electrical character of a conductive system may be defined by “motion” of monopoles, such as in ionic hopping or electron transfer. The electrical resistance of a circuit component or device the ratio of the voltage applied to the electric current that flows through it: I=V/R. The resistivity, and thus the resistance, may be temperature dependent. Over sizable ranges of temperature, the temperature dependence can be predicted from a temperature coefficient of resistance. An electrical dispersivity of the cured electrically conductive polymer may be less than about 10⁻⁵ Ohm centimeter at room temperature. In one embodiment, the electrical dispersivity may be in a range of from about 10⁻⁵ Ohm centimeter to about 10⁻⁶ Ohm centimeter, or less than about 10⁻⁶ Ohm centimeter at about room temperature.

The bump structure's thermal conductivity may be greater than about 1.5 watt per meter Kelvin at about 120 degrees Celsius. In one embodiment, the thermal conductivity may be in a range of from about 1.5 watt per meter Kelvin to about 2 watt per meter Kelvin, from about 2 watt per meter Kelvin to about 2.2 watt per meter Kelvin, or greater than about 2.2 watt per meter Kelvin.

The bump structure and the underfill layer, after cure, may have one or more of a high glass transition temperature (greater than about 100 degrees Celsius), a high yield stress, a linear elastic response over a large stress-strain region, and a high compressive strength. High glass transition temperature may be required for assemblies that operate at high temperatures.

In one embodiment, the bump structure and/or the underfill layer may increase the heat dissipation of thermal energy from the electronics package to the environment. For example, the bump structure and/or the underfill layer may facilitate heat transfer from the chip to the substrate. The substrate in turn may be coupled to a heat-dissipating unit, such as a heat sink, a heat radiator, a heat spreader, a lid, a heat pipe, or a Peltier heat pump. In one embodiment, the electrically conductive polymer may include a heat pipe disposed therein.

As with the underfill layer, the bump structure may include an initially present solvent. Suitable solvents may include one or more organic solvents, such as 1-methoxy-2-propanol, methoxy propanol acetate, butyl acetate, methoxyethyl ether, methanol, ethanol, isopropanol, ethyleneglycol, methylethyl ketone, cyclohexanone, benzene, toluene, xylene, and cellosolves such as ethylcellosolve, ethyl acetate, cellosolve acetate, butyl cellosolve acetate, carbitol acetate, and butyl carbitol acetate, and combinations of two or more thereof. These solvents may be used either singly or in the form of a combination of two or more members. In at least one embodiment, the solvent may be extracted to form a B-staged layer.

The bump structure and the underfill layer, taken together, define a laminate. The laminate may be a single integrated structure that includes at least the bump structure and the underfill layer.

The laminate may be free of a fluxing agent. If a fluxing agent is present, the fluxing agent may include one or more of an aliphatic linear carboxylic acid, an aliphatic non-linear carboxylic acid, an alcohol, an amine, an amine salt, an aromatic iodonium salt, or a combination of two or more thereof.

The laminate may be B-stageable, and when B-staged, may be a disposed on a substrate or may be free standing. In one embodiment, the coefficient of thermal expansion of the underfill layer is about the same as the coefficient of thermal expansion of the bump structure to avoid thermal mismatch between the two materials at operating temperatures. For example, the coefficient of thermal expansion of the underfill layer and the bump structure may be less than about 100 ppm per degrees Celsius, or in a range of from about 2 ppm per degrees Celsius to about 80 ppm per degrees Celsius, or from about 5 ppm per degrees Celsius to about 50 ppm per degrees Celsius.

In one embodiment, the bump structure may have lower cure temperatures than the cure temperatures of the underfill layer. Further, the cure temperature of the bump structure may be in a range of from about 30 degrees Celsius to about 200 degrees Celsius, from about 45 degrees Celsius to about 175 degrees Celsius, from about 60 degrees Celsius to about 160 degrees Celsius, or from about 70 degrees Celsius to less than about 150 degrees Celsius. The cure temperatures of the underfill layer may be in a range of from about 30 degrees Celsius to about 80 degrees Celsius, from about 80 degrees Celsius to about 130 degrees Celsius, from about 130 degrees Celsius to about 150 degrees Celsius, or greater than about 150 degrees Celsius.

In one embodiment, the underfill layer may be cured to define one or more openings or cavities. The openings may extend partially or entirely through the underfill layer. The curing may be performed prior to disposing the bump structure in the openings. In another embodiment, the bump structure(s) may define an array around which the underfill layer may be disposed. The bump structure and the underfill layer may be cured in a determined order, or may be B-staged to an intermediate hardness prior to cure.

An electronics package according to an embodiment of the invention may include an assembly. The assembly may provide thermal communication and/or electrical communication from a heat-generating unit to a heat-dissipating unit. As described above, the electronics package may include a laminate. The laminate may include an underfill layer having a surface that defines an opening, and a bump structure disposed within the opening of the underfill layer.

Suitable heat-generating units may include one or more of an integrated chip, a power chip, power source, light source (e.g., LED, fluorescent, or incandescent), motor, sensor, capacitor, fuel storage compartment, conductor, inductor, switch, diode, or transistor. Suitable heat-dissipating units may include one or more of a heat sink, a heat radiator, a heat spreader, a lid, a heat pipe, or a Peltier heat pump.

To make an electronics package, an underfill layer may be disposed on a substrate. The underfill layer may be patterned by a dispensing technique to define one or more openings (e.g., a cavity or aperture). Lithography and printing techniques may be used to dispense the underfill layer, and to define or create the opening. The opening may be formed by creating a layer and then removing material from the layer to define the opening, or by dispensing material in a determined manner to define the opening. A bump structure may be dispensed into the opening.

With regard to lithography, the underfill layer may be a photoresist material. A pattern may be formed in the underfill layer by masking the underfill layer with a patterned mask. For example, photolithography may be employed to pattern the underfill layer to define the cavities. The underfill layer with a photomask disposed thereon may be exposed to a certain radiation. Subsequently, the exposed portions of the layer may be removed to define cavities by patterning the underfill layer. The portions of the underfill layer may be removed by, for example, etching. A wet etch process or dry etch process may be used to define the openings.

B-staging of the B-stage layer may be performed on the underfill layer before or after disposing electrically conductive polymer in the respective openings. Rather than using a B-stage underfill layer material a radiation-cure underfill layer material may be used so that the underfill layer may be cured by exposure to, for example, ultraviolet radiation.

In one embodiment, disposing the underfill layer may include depositing underfill material on the substrate in the form of a layer, and subsequently patterning the underfill layer to define one or more openings. For example, squeezing, roll coating, spraying, or brushing may apply the underfill layer onto the substrate, or onto the under bump metallurgy formed on the substrate. In one embodiment, at least a portion of the under bump metallurgy may be deposited on a substrate by sputtering.

The bump structure may be deposited in the opening by printing or by syringe dispensing. Other dispensing methods may include lamination, spraying, and spin coating.

The deposited bump structure may form a concave profile at the mouth of the opening extending outward from the surface. The concave profile of the bump structure may facilitate the coupling of the bump structure with the electrical interconnects on the chip assembly. The bump structure may first contact the interconnects or contact pads before the underfill layer. In one embodiment, the electrically conductive polymer may overflow from the cavities and may cover a portion of the underfill layer (e.g., to form a mushroom shape).

Another method may include dispensing or disposing one or more bump structures on a substrate. The bump structures may be B-staged or thermoformed. An underfill layer material may be contacted with and/or flowed about and around the bump structure. The underfill layer may form an opening around the bumps.

Disposing the bump structure may include one or more of printing, syringe dispensing, or pick-and-place dispensing. In one embodiment, printing may include one or more of flexographic printing, screen-printing, jet printing, or stencil printing.

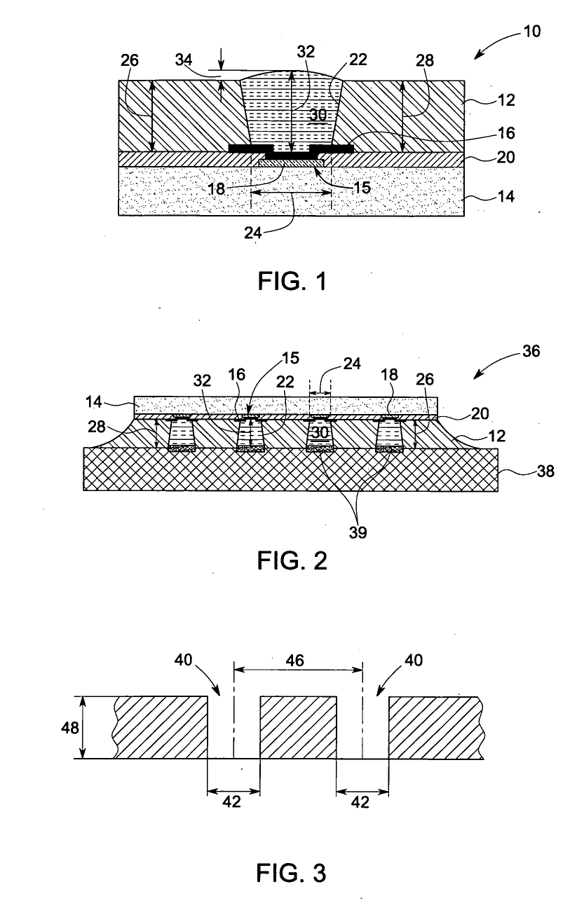

An electronics package 10 is shown in FIG. 1. The assembly 10 includes a B-staged underfill layer laminate 12 disposed on a silicon substrate 14 having under bump metallurgy 15. The under bump metallurgy 15 may include a plurality of contact pads 16, an aluminum layer 18, and a passivation layer 20. The contact pads 16 may be aluminum. The passivation layer 20 may be silicon nitride. The underfill layer 12 has an inner surface 22 that defines an opening. The opening has a diameter 24. The opening diameter 24 is a measure of the aperture defined where the opening couples to the substrate 14. A height 26 of the opening is the same as the thickness 28 of the underfill layer 12.

An electrically conductive polymer is disposed within the opening to define a bump structure 30. A height 32 of the bump structure 30 is a vertical distance from the opposing surface of the underfill layer 12 to the highest point in the profile of the other end of the electrically conductive polymer 30. The height 32 of the bump structure 30 is more than the opening height 26 because the bump structure 30 extends further outward relative to the surface of the underfill layer 12. The height difference 34 may facilitate electrical connection of the bump structure 30 and one or more of the contact pads 16.

An assembly 36 employing the electronics package 10 of FIG. 1 is shown in FIG. 2. The electronics package 10 is in an inverted orientation relative to the orientation of FIG. 1 and is coupled to a printed circuit board (PCB) 38. The underfill layer 12 is cured.

FIG. 3 is a schematic view illustrating the distribution of an array of openings 40 in the underfill layer. The openings 40 are in a determined pattern that is designed to correspond to electrical interconnects during the end use. The openings 40 have a diameter 42, a pitch 46, and a height 48. In the illustrated embodiment, the diameter 42 is about 15 micrometers, the pitch 46 is about 25 micrometers, and the height 48 is about 100 micrometers.

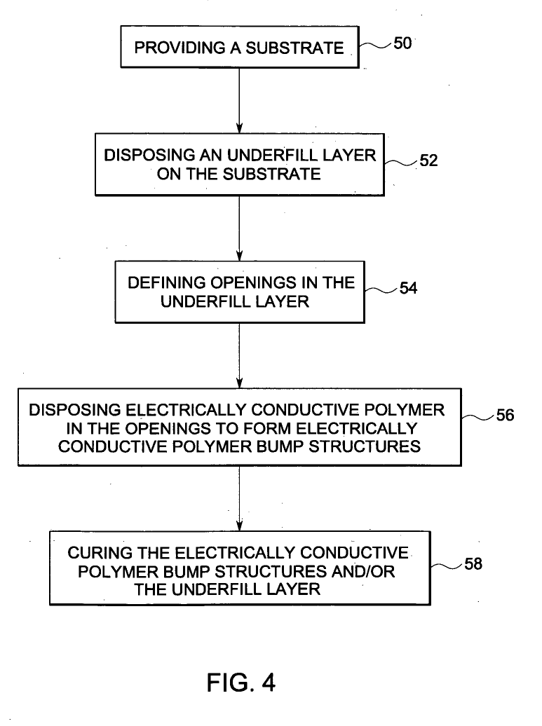

FIG. 4 is a flow chart illustrating a method of making an electronics package. A substrate is provided (block 50), and underfill layer is disposed on a surface of the substrate (block 52). The openings are cut or ablated in the underfill layer (block 54). An electrically conductive polymer is disposed in the openings to form electrically conductive polymer bump structures (block 56). Optionally, the bump structure and the underfill layer may be B-staged together to form a laminate, the bump structure may be contacted to an electrical interconnect, and then the laminate may be cured (block 58).

The foregoing examples are merely illustrative of some of the features of the invention. The appended claims are intended to claim the invention as broadly as it may have been conceived and the examples herein presented are illustrative of selected embodiments from a manifold of all possible embodiments. Accordingly it is Applicants' intention that the appended claims are not to be limited by the choice of examples utilized to illustrate features of the invention. Where necessary, ranges have been supplied, those ranges are inclusive of all sub-ranges there between. It is to be expected that variations in these ranges will suggest themselves to a practitioner having ordinary skill in the art and where not already dedicated to the public, those variations should be covered by the appended claims. Advances in science and technology will make equivalents and substitutions possible that are not now contemplated by reason of the imprecision of language and these variations should also be construed where possible to be covered by the appended claims.

1. An electronics package, comprising
an underfill layer having a surface that defines an opening;
a bump structure disposed within the opening, wherein the bump structure comprises an inherently electrically conductive polymer.

2. The electronics package as defined in claim 1, wherein the bump structure extends outward from the underfill layer surface.

3. The electronics package as defined in claim 1, wherein the underfill layer is a radiation curable polymeric precursor that responds to radiation by polymerizing.

4. The electronics package as defined in claim 3, wherein the radiation is ultraviolet radiation.

5. The electronics package as defined in claim 1, wherein the underfill layer material comprises a B-stageable underfill layer material.

6. The electronics package as defined in claim 5, wherein the B-stageable underfill layer material comprises a solvent when in an uncured and not B-staged state.

7. The electronics package as defined in claim 5, wherein the B-stageable underfill layer material comprises a first curable material and a second curable material, and the cure mechanism of the first curable material is different that the cure mechanism of the second curable material.

8. The electronics package as defined in claim 1, wherein the underfill layer comprises a filler.

9. The electronics package as defined in claim 8, wherein the filler comprises one or more of an oxide, a nitride, a boride, or combinations of two or more thereof.

10. The electronics package as defined in claim 8, wherein the filler is electrically insulating filler.

11. The electronics package as defined in claim 8, wherein the filler comprises spherical particles.

12. The electronics package as defined in claim 8, wherein the filler comprises particles, each having a length that differs from a width.

13. (canceled)

14. The electronics package as defined in claim 1, wherein the bump structure is free of electrically conductive filler, and the bump structure is electrically conductive.

15. The electronics package as defined in claim 1, wherein the bump structure further comprises electrically conductive filler, and the bump structure is electrically conductive.

16. The electronics package as defined in claim 15, wherein the bump structure comprises a conductive metal.

17. The electronics package as defined in claim 16, wherein the bump structure comprises a liquid metal or silver.

18. The electronics package as defined in claim 1, wherein the bump structure is free of lead.

19. The electronics package as defined in claim 1, wherein the bump structure further comprises thermally conductive filler.

20. The electronics package as defined in claim 1, wherein the bump structure further comprises electrically conductive particles having an average particle size in a range of less than about 1000 nanometers.

21. The electronics package as defined in claim 1, wherein the bump structure comprises a fluxing agent.

22. The electronics package as defined in claim 1, wherein a pitch of the bump structure is less than about 50 micrometers.

23. The electronics package as defined in claim 1, wherein a cure temperature of the bump structure is in a temperature range of less than about 150 degrees Celsius.

24. The electronics package as defined in claim 1, wherein the bump structure is cured.

25. The electronics package as defined in claim 24, wherein an electrical resistivity of the cured bump structure is less than about 10⁻⁵ Ohm centimeter.

26. The electronics package as defined in claim 24, wherein an electrical resistivity of the cured bump structure is less than about 10⁻³ Ohm centimeter.

27. The electronics package as defined in claim 1, wherein the underfill layer is B-staged.

28. The electronics package as defined in claim 1, wherein the underfill layer is cured.

29. The electronics package as defined in claim 28, wherein the underfill layer has a coefficient of thermal expansion about the same as the coefficient of thermal expansion of the electrically conductive polymer when both layers are cured.

30. A wafer level underfill assembly comprising the electronics package as defined in claim 1.

31. The assembly of claim 30, comprising a flip chip assembly.

32. The assembly of claim 30, further comprising an under bump metallurgy.

33. A method of making an electronics package, comprising:
disposing a bump structure comprising an inherently electrically conductive polymer in an opening defined by a surface of an underfill layer to form a laminate, or
disposing a bump structure comprising an inherently electrically conductive polymer on a substrate, and contacting an underfill layer material to the bump structure to form the laminate.

34. The method as defined in claim 33, wherein disposing the bump structure comprises one or more of printing, syringe dispensing, or coating.

35. The method as defined in claim 33, further comprising defining the opening in the underfill layer by one or more of photolithography, wet etch process, or dry etch process.

36. The method as defined in claim 33, further comprising B-staging the underfill layer.

37. The method as defined in claim 33, further comprising curing the bump structure, curing the underfill layer, or curing both the bump structure and the underfill layer.

38. A laminate, comprising a B-staged underfill layer having a polymeric bump structure disposed therein.

39. The laminate as defined in claim 38, wherein the bump structure is in electrical contact with one or more electrical interconnects, and the laminate is cured.
